(19) United States
(12) Patent Application Publication
(10) Pub. No.: US 2024/0411941 A1
(43) Pub. Date: Dec. 12, 2024

(54) HYBRID SYSTEM FOR PREDICTING AUDIO IMPULSE RESPONSE

(71) Applicant: Biamp Systems, LLC, Beaverton, OR (US)

(72) Inventors: Xian Chloe Yu, Bryn Mawr, PA (US); Charles Emory Hughes, II, Gastonia, NC (US)

(73) Assignee: Biamp Systems, LLC, Beaverton, OR (US)

(21) Appl. No.: 18/207,119

(22) Filed: Jun. 7, 2023

(51) Int. Cl. G06F 30/12; H04S 7/00

(52) U.S. Cl. CPC G06F 30/12; H04S 7/305; H04S 7/40

(57) ABSTRACT

An example operation may include one or more of storing one or more statistical models, storing one or more ray-tracing models, simulating a first portion of an audio impulse response via execution of ray-tracing algorithm on characteristics of a venue, predicting a second portion of the audio impulse response via execution of the one or more statistical models on the characteristics of the venue, combining the simulated first portion of the audio impulse response and the predicted second portion of the audio impulse response into a composite audio impulse response, and displaying the composite audio impulse response via a user interface.

### BACKGROUND

The acoustic response of loudspeakers within a venue, such as a room, an auditorium, a hall, and the like, can be predicted in advance using various methods in the art such as ray-tracing, statistical models, and the like. Ray-tracing requires a computer, or a group of computers, to execute a great deal of simulations based on room acoustic characteristics. However, one of the main drawbacks of ray-tracing is that it requires a significant amount of computer processing that can take hours or longer. Meanwhile, other computer simulations can be used to provide a quick estimation of the audio response, however, the simulations are not very accurate. As just one example, statistical simulations do not take into account arrival time differences from multiple loudspeakers which can have adverse effects on the predicted results. Accordingly, a new approach for acoustic response prediction is needed.

### SUMMARY

One example embodiment provides an apparatus that may include a storage configured to store one or more statistical models, and a processor configured to simulate a first portion of an audio response signal via execution of ray-tracing algorithm on characteristics of a venue, predict a second portion of the audio response signal via execution of the one or more statistical models on the characteristics of the venue, combine the simulated first portion of the audio response signal and the predicted second portion of the audio response signal into a composite audio response signal, and display the composite audio response signal via a user interface.

Another example embodiment provides a method that includes one or more of storing one or more statistical models, simulating a first portion of an audio response signal via execution of ray-tracing algorithm on characteristics of a venue, predicting a second portion of the audio response signal via execution of the one or more statistical models on the characteristics of the venue, combining the simulated first portion of the audio response signal and the predicted second portion of the audio response signal into a composite audio response signal, and displaying the composite audio response signal via a user interface.

A further example embodiment provides a computer-readable medium comprising instructions, that when read by a processor, cause the processor to perform one or more of storing one or more statistical models, simulating a first portion of an audio response signal via execution of ray-tracing algorithm on characteristics of a venue, predicting a second portion of the audio response signal via execution of the one or more statistical models on the characteristics of the venue, combining the simulated first portion of the audio response signal and the predicted second portion of the audio response signal into a composite audio response signal, and displaying the composite audio response signal via a user interface.

### BRIEF DESCRIPTION OF THE DRAWINGS

FIG. 1 is a diagram illustrating a process of simulating an audio response signal within a venue according to example embodiments.

FIG. 2 is a diagram illustrating an example of a hybrid system that can perform the process shown in FIG. 1, according to example embodiments.

FIG. 3A is a diagram illustrating an example of the initial part (head) of a RIR generated by the hybrid system shown in FIG. 2, according to example embodiments.

FIG. 3B is a diagram illustrating an example of another part (tail) of a RIR generated by the hybrid system shown in FIG. 2, according to example embodiments.

FIG. 3C is a diagram illustrating an example combination of the RIR head and tail from FIG. 3A and FIG. 3B into a composite RIR generated by the hybrid system shown in FIG. 2, according to example embodiments.

FIG. 4 is a diagram illustrating a method of generating an impulse response based on a hybrid system according to example embodiments.

FIG. 5 is a diagram illustrating an example system that supports one or more of the example embodiments described herein.

### DETAILED DESCRIPTION

It is to be understood that although this disclosure includes a detailed description of cloud computing, implementation of the teachings recited herein is not limited to a cloud computing environment. Rather, embodiments of the instant solution are capable of being implemented in conjunction with any other type of computing environment now known or later developed.

An acoustical impulse response aims to model the reverberant properties of a space (e.g., a venue). An acoustical impulse response is typically generated by radiating sound outward from an excitation source while in a room (or other venue) and bouncing the sound around the room (or other venue). Sound traveling by the most direct path (e.g., a straight line from the source to a measurement position, etc.) arrives first and is expected to be the loudest. Reflected sound arrives later by a multitude of paths, losing energy to air and surface absorption along the way so that later arrivals tend to come in at lower and lower levels. However, physical measurements require equipment, time, and use of the venue.

Instead of performing physical measurements, the acoustic impulse response of the room can be “simulated” without ever being in the room. As an example, the acoustic response of loudspeakers in a venue can be predicted by statistical methods or ray-tracing mathematical modeling methods. But both methods have significant drawbacks and are therefore not as accurate as a process of performing the physical measurements. For example, the statistical method provides a quick estimation of the sound pressure level (SPL), frequency response (FR), and speech transmission index (STI) at a given listener location and is used to predict room acoustics. However, it does not take into account the arrival time differences from multiple loudspeakers, which may adversely affect the accuracy of predicted results.

Meanwhile, the ray-tracing method computes a room impulse response (RIR) for a given listener location using the room acoustic characteristics, and the location, aiming, sensitivity, and directivity of each loudspeaker. The RIR describes the acoustic performance of the loudspeakers in the room. The arrival time of each loudspeaker is accurately reflected in a sample index in the RIR. Using the RIR, auralization at the listener location can be rendered, and SPL, FR, and STI can also be derived. Auralization is the process of rendering audible a sound field of a source in space by physical or mathematical modeling. The ray-tracing method generally offers greater precision with a sufficient order of reflections. However, the computing complexity of the ray-tracing process increases exponentially as the order of reflections increases.

The example embodiments are directed to a hybrid room impulse response (Hybrid RIR) creation system and process that utilizes a combination of ray-tracing method for simulating direct sound and early reflections (head region) of an RIR and then utilizes a statistical method to simulate a reverberant decay (tail region) of the RIR. The hybrid system takes advantage of the accuracies provided by ray-tracing within the head region of the RIR, and then takes advantage of the computational benefits of the statistical simulation within the tail region of the RIR. As a result, a composite RIR can be generated in an amount of time that is significantly faster time than it takes to perform ray-tracing of an entire RIR, and with significantly more accuracy than with statistical simulation.

As an example, the hybrid system may be an acoustic engine that is integrated into a software program such as a software application, such as “Warehouse Designer” which is a web application under development at BIAMP®. Here, the software application may predict a sound pressure level (SPL), frequency response (FR), and speech transmission index (STI), as well as the auralization feature of multiple loudspeakers in a venue. The hybrid system described herein is the acoustic engine within the application that can use a combination of ray-tracing and statistical prediction to simulate an audio impulse response in much faster time than traditional ray-tracing methods, with similar accuracy. The system overcomes the slowness of ray-tracing by combining statistical prediction, and it overcomes the lack of accuracy of the statistical methods by combining ray-tracing. For example, the system described herein is more accurate when there are multiple loudspeakers to include in a simulation of the venue.

The host system described herein may utilize the ray-tracing simulation process to generate a head of an impulse response which consists of the direct sound and early reflections. The host system may simulate a number of different rays (sound rays) in different directions and trace the results. The system then pivots and uses a statistically calculated reverberation time (RT) and direct-to-reverb ratio (DRR) to create a tail region of the impulse response where the statistically calculated RT controls the decay slope, and the statistically calculated DRR controls the overall amplitude of the RIR tail in relation to the RIR head. The two different portions of the RIR can then be combined into a single composite RIR that is rendered on a user interface such as a page of the software application.

The system generates a predicted impulse response in significantly faster time than ray-tracing and is more accurate than statistical modeling algorithms. For example, the host system described herein can account for different arrival times from multiple loudspeakers. Test results of the host system were compared to results from commercially available 3D simulation software of various room models where statistical acoustics are applicable. During testing, the host system descried herein achieved comparable SPL and STI results to the off-the shelf 3D simulation software while significantly reducing the computing time by as much as 90 percent in comparison to the 3D simulation software. In an example room model with 10 loudspeakers and 30 listener locations, the 3D simulation software required 2 minutes 22 seconds, while the host system only took 15 seconds to generate quite similar results. This quick computation capability lends itself to a practical web-based application.

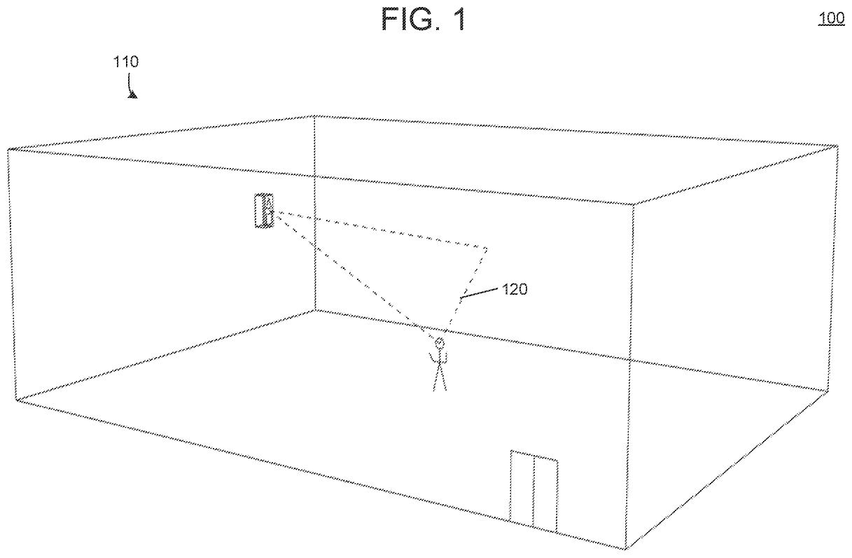

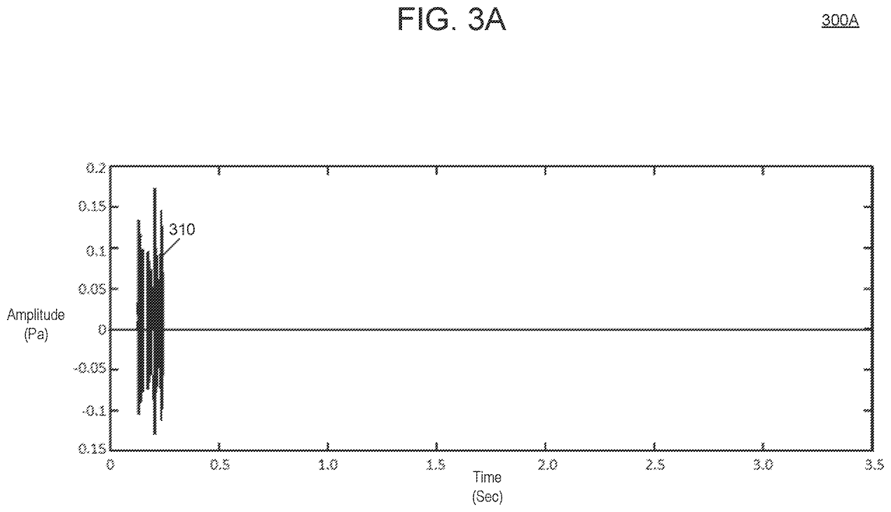

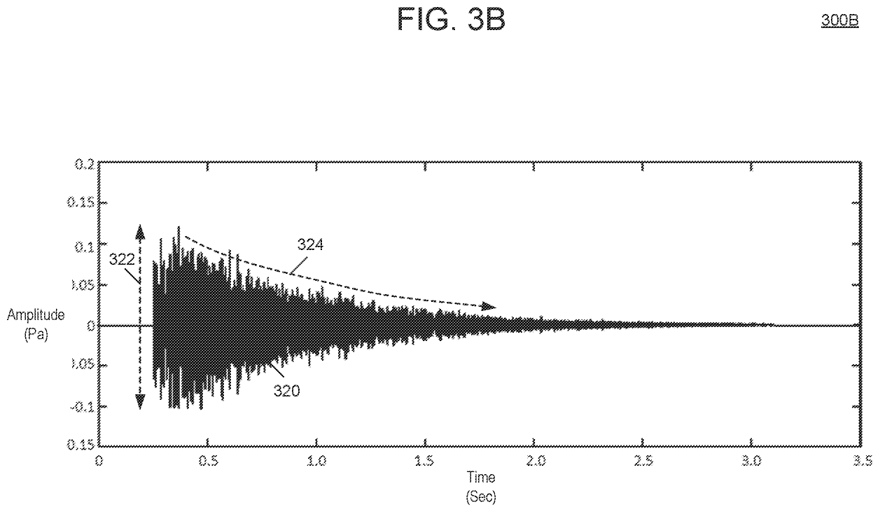

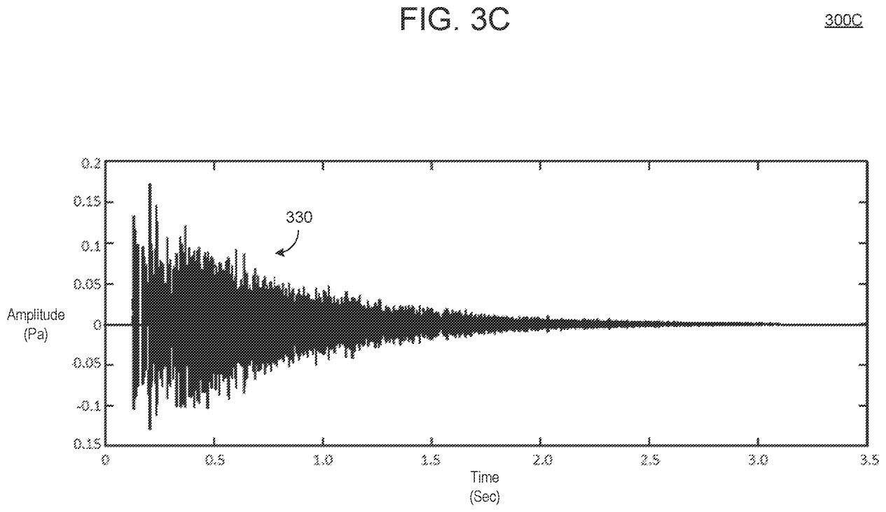

FIG. 1 is a diagram illustrating a process 100 of simulating an audio impulse response within a venue 110 according to example embodiments. As noted already, the example embodiments may use a host system such as shown in FIG. 3, to simulate an impulse response 122 (i.e., an audio response) within a fixed space such as the venue 110. The system may use a combination of ray-tracing and statistical modeling for the simulation of the impulse response.

Ray-tracing starts out at a sound source such as a point in the room, and simulates/emits sound waves (rays) in uniformly random directions at the same time, travelling at the speed of sound. When a ray hits a boundary, it loses some of its energy, depending on the properties of the boundary's material. Then, the ray is reflected. When it intersects the receiver, the energy and propagation time of the ray are recorded. In ray tracing, each ray represents a finite portion of the initial source energy. The reduction of energy over a given distance is accounted for by the spreading-out of the rays.

Meanwhile, statistical modeling uses a mathematical model(s) to estimate an impulse response. The model(s) may use the same input data as the ray-tracing simulation process, however, the results are much faster and less accurate. In some embodiments, the system described herein uses a first statistical model to estimate a decay rate of the tail portion of the impulse response, and uses a second statistical model to estimate an amplitude of the tail portion of the impulse response.

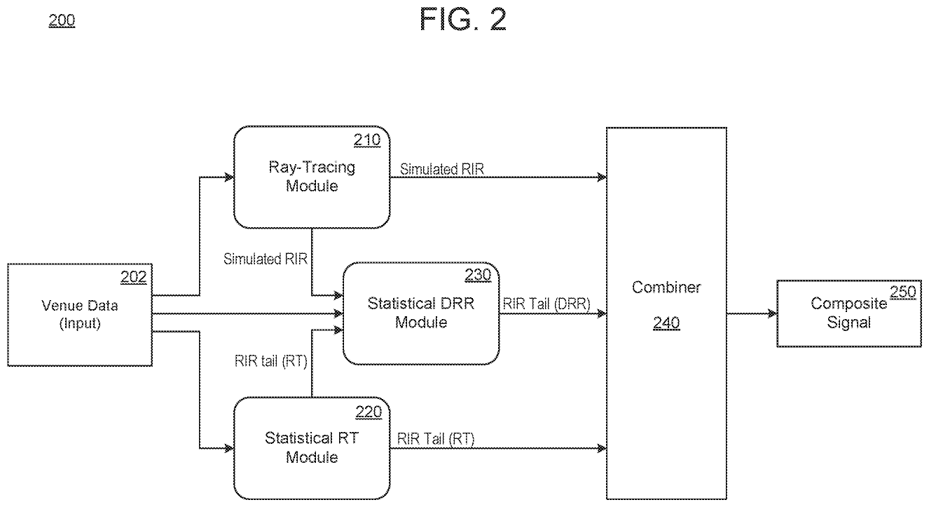

FIG. 2 illustrates an example of a hybrid system 200 that can perform the process shown in FIG. 1, according to example embodiments. Referring to FIG. 2, input data 202 to the system may include room geometry data/measurements, absorption coefficients of room surfaces, listener/receiver locations, loudspeaker locations, loudspeaker transfer functions, and loudspeaker directivities. In the example of FIG. 2, the input data 202 is input into a ray tracing module 210, a statistical RT module 220, and a statistical DRR module 230.

Here, the ray tracing module 210 may perform a simulation of the room impulse response for an initial head portion (e.g., shown in FIG. 3A) of a RIR which consists of the direct sound from the loudspeaker(s) and early reflections up to a predefined cutoff order. For example, the ray-tracing module 210 may collect the reflection paths of a given order. For example, a 1st order reflection means that the sound emitted by the loudspeaker gets reflected by room surfaces one time before reaching the receiver, a 2nd order reflection means it gets reflected two times, and the like. Each reflection path contains a series of reflection points in the order of time occurrence, where the number of reflection points equals the reflection order. The algorithm stops once it has collected reflections up to the cutoff order. The cutoff order is determined dynamically by the algorithm and generally depends on the room size and the distance between the loudspeaker and receiver. The direct sound and reflections are combined in the time domain according to their time occurrence. The amplitude of each arrival depends on the loudspeaker location, loudspeaker transfer function, loudspeaker directivity, absorption coefficient of each reflecting surface, and the receiver location. This procedure is repeated at multiple frequency bands since the loudspeaker transfer function, loudspeaker directivity, and surface absorption coefficients are frequency dependent. The results from each frequency band are then combined to form the impulse response head.

In addition, the statistical RT module 220 may receive the room geometry, absorption coefficients of each room surfaces, etc., and calculate a reverberation time (RT) for the room impulse response based on a statistical model. The output may include a reverberation time at multiple frequency bands. Meanwhile, the statistical DRR module 230 may receive the input data 202, the output from the ray-tracing simulator module 210, and the output from the statistical RT module 220, and determine a tail part (e.g., shown in FIG. 3B) of the room impulse response which consists of a statistical reverberant field. Here, the DRR module 230 may calculate a direct-to-reverberant ratio using a statistical model, create a decay slope of the given reverberation time, create an impulse response tail based on a decay slope that is convolved with white noise, then its amplitude is scaled to achieve the direct-to-reverberant ratio. This procedure is repeated at multiple frequency bands since the reverberation time and direct-to-reverberant ratio are frequency dependent. The results from each frequency band are then combined to form the impulse response tail

Next, a combiner 240 receives the simulated head part of the RIR from the ray-tracing module 210 and the tail part of the RIR from the statistical DRR module 230, and generates a composite signal 250 (e.g., shown in FIG. 3C) that includes both the head and the tail parts of the acoustical response. The combiner 240 may sum the impulse response head and tail in time domain. This procedure is repeated at multiple frequency bands.

FIG. 3A is a diagram illustrating an example of the initial part (head) of a RIR generated by the ray-tracing module 210 shown in FIG. 2, according to example embodiments. FIG. 3B is a diagram illustrating an example of another part (tail) of a RIR generated by the statistical DRR module 230 shown in FIG. 2, according to example embodiments. FIG. 3C is a diagram illustrating an example combination of the RIR head and tail from FIG. 3A and FIG. 3B into a composite RIR generated by the combiner 240 shown in FIG. 2, according to example embodiments.

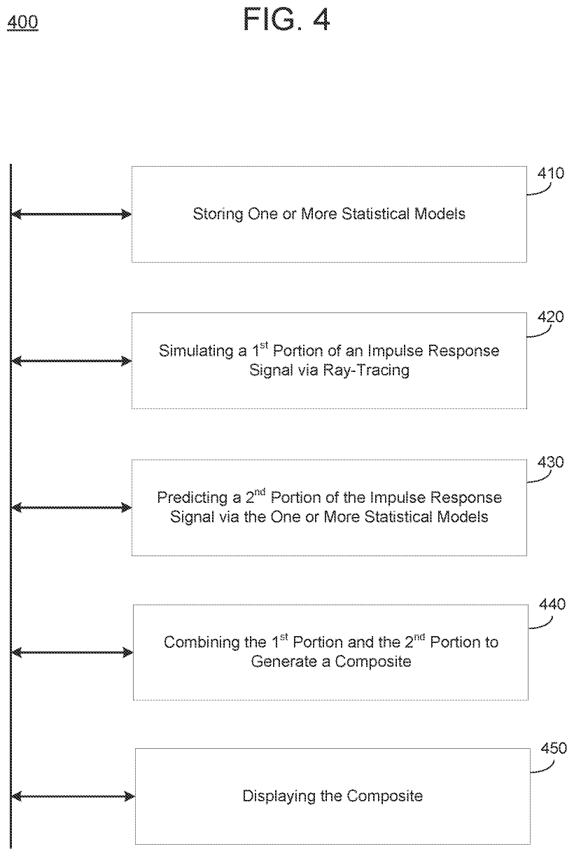

FIG. 4 illustrates a method 400 of generating an impulse response based on a hybrid system according to example embodiments. For example, the method may be performed by a software application hosted on a platform such as a web server, a cloud platform, a database, an on-premises server, a desktop computer, a laptop, a mobile device, and the like. Referring to FIG. 4, in 410, the method may include storing one or more statistical models. As an example, the statistical models may include a first model configured to simulate a decay rate of a portion of the impulse response (e.g., reverberation time) and a second model configured to simulate an amplitude of the portion of the impulse response.

In 420, the method may include simulating a first portion of an audio impulse response via execution of ray-tracing algorithm on characteristics of a venue. In 430, the method may include predicting a second portion of the audio impulse response via execution of the one or more statistical models on the characteristics of the venue. In 440, the method may include combining the simulated first portion of the audio impulse response and the predicted second portion of the audio impulse response into a composite audio impulse response. In 450, the method may include displaying the composite audio impulse response via a user interface.

In some embodiments, the characteristics of the venue may include geometric attributes of a space, and locations of one or more loudspeakers within the space. In some embodiments, the method may include simulating a head region of the audio impulse response via execution of the ray-tracing algorithm, wherein the head region represents direct sound and early reflections.

The above embodiments may be implemented in hardware, in a computer program executed by a processor, in firmware, or in a combination of the above. A computer program may be embodied on a computer readable medium, such as a storage medium. For example, a computer program may reside in random access memory (“RAM”), flash memory, read-only memory (“ROM”), erasable programmable read-only memory (“EPROM”), electrically erasable programmable read-only memory (“EEPROM”), registers, hard disk, a removable disk, a compact disk read-only memory (“CD-ROM”), or any other form of storage medium known in the art.

An exemplary storage medium may be coupled to the processor such that the processor may read information from, and write information to, the storage medium. In the alternative, the storage medium may be integral to the processor. The processor and the storage medium may reside in an application-specific integrated circuit (“ASIC”). In the alternative, the processor and the storage medium may reside as discrete components. For example, FIG. 6 illustrates an example computer system architecture 500, which may represent or be integrated in any of the above-described components, etc.

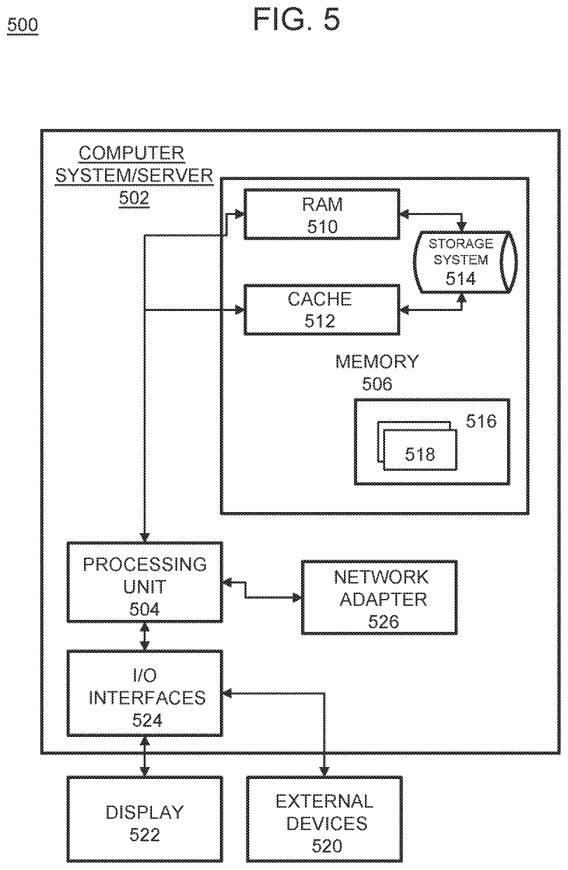

FIG. 5 illustrates an example system 500 that supports one or more of the example embodiments described and/or depicted herein. The system 500 comprises a computer system/server 502, which is operational with numerous other general purpose or special purpose computing system environments or configurations. Examples of well-known computing systems, environments, and/or configurations that may be suitable for use with computer system/server 502 include, but are not limited to, personal computer systems, server computer systems, thin clients, thick clients, hand-held or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 502 may be described in the general context of computer system-executable instructions, such as program modules, being executed by a computer system. Generally, program modules may include routines, programs, objects, components, logic, data structures, and so on that perform particular tasks or implement particular abstract data types. Computer system/server 502 may be practiced in distributed cloud computing environments where tasks are performed by remote processing devices that are linked through a communications network. In a distributed cloud computing environment, program modules may be located in both local and remote computer system storage media, including memory storage devices.

As shown in FIG. 5, computer system/server 502 in cloud computing node 500 is shown in the form of a general-purpose computing device. The components of computer system/server 502 may include, but are not limited to, one or more processors or processing units 504, a system memory 506, and a bus that couples various system components, including system memory 506 to processor 504.

The bus represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 502 typically includes a variety of computer system readable media. Such media may be any available media that is accessible by computer system/server 502, and it includes both volatile and non-volatile media, removable and non-removable media. System memory 506, in one embodiment, implements the flow diagrams of the other figures. The system memory 506 can include computer system readable media in the form of volatile memory, such as random-access memory (RAM) 510 and/or cache memory 512. Computer system/server 502 may further include other removable/non-removable, volatile/non-volatile computer system storage media. By way of example only, storage system 514 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”) and an optical disk drive for reading from or writing to a removable, non-volatile optical disk such as a CD-ROM, DVD-ROM or other optical media can be provided. In such instances, each can be connected to the bus by one or more data media interfaces. As will be further depicted and described below, memory 506 may include at least one program product having a set (e.g., at least one) of program modules that are configured to carry out the functions of various embodiments of the application.

Program/utility 516, having a set (at least one) of program modules 518, may be stored in memory 506 by way of example, and not limitation, as well as an operating system, one or more application programs, other program modules, and program data. Each of the operating system, one or more application programs, other program modules, and program data or some combination thereof may include an implementation of a networking environment. Program modules 518 generally carry out the functions and/or methodologies of various application embodiments as described herein.

As will be appreciated by one skilled in the art, aspects of the present application may be embodied as a system, method, or computer program product. Accordingly, aspects of the present application may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present application may take the form of a computer program product embodied in one or more computer readable medium(s) having computer readable program code embodied thereon.

Computer system/server 502 may also communicate with one or more external devices 520 such as a keyboard, a pointing device, a display 522, etc.; one or more devices that enable a user to interact with computer system/server 502; and/or any devices (e.g., network card, modem, etc.) that enable computer system/server 502 to communicate with one or more other computing devices. Such communication can occur via I/O interfaces 524. Still yet, computer system/server 502 can communicate with one or more networks such as a local area network (LAN), a general wide area network (WAN), and/or a public network (e.g., the Internet) via network adapter 526. As depicted, network adapter 526 communicates with the other components of computer system/server 502 via a bus. It should be understood that although not shown, other hardware and/or software components could be used in conjunction with computer system/server 502.

Examples include, but are not limited to: microcode, device drivers, redundant processing units, external disk drive arrays, RAID systems, tape drives, data archival storage systems, etc.

Although an exemplary embodiment of at least one of a system, method, and computer readable medium has been illustrated in the accompanying drawings and described in the foregoing detailed description, it will be understood that the application is not limited to the embodiments disclosed but is capable of numerous rearrangements, modifications, and substitutions as set forth and defined by the following claims. For example, the system's capabilities of the various figures can be performed by one or more of the modules or components described herein or in a distributed architecture and may include a transmitter, receiver, or pair of both. For example, all or part of the functionality performed by the individual modules may be performed by one or more of these modules. Further, the functionality described herein may be performed at various times and in relation to various events, internal or external to the modules or components. Also, the information sent between various modules can be sent between the modules via at least one of: a data network, the Internet, a voice network, an Internet Protocol network, a wireless device, a wired device and/or via a plurality of protocols. Also, the messages sent or received by any of the modules may be sent or received directly and/or via one or more of the other modules.

One skilled in the art will appreciate that a “system” could be embodied as a personal computer, a server, a console, a personal digital assistant (PDA), a cell phone, a tablet computing device, a smartphone, or any other suitable computing device, or combination of devices. Presenting the above-described functions as being performed by a “system” is not intended to limit the scope of the present application in any way but is intended to provide one example of many embodiments. Indeed, methods, systems, and apparatuses disclosed herein may be implemented in localized and distributed forms consistent with computing technology.

It should be noted that some of the system features described in this specification have been presented as modules in order to more particularly emphasize their implementation independence. For example, a module may be implemented as a hardware circuit comprising custom very large-scale integration (VLSI) circuits or gate arrays, off-the-shelf semiconductors such as logic chips, transistors, or other discrete components. A module may also be implemented in programmable hardware devices such as field programmable gate arrays, programmable array logic, programmable logic devices, graphics processing units, or the like.

A module may also be at least partially implemented in software for execution by various types of processors. An identified unit of executable code may, for instance, comprise one or more physical or logical blocks of computer instructions that may, for instance, be organized as an object, procedure, or function. Nevertheless, the executables of an identified module need not be physically located together but may comprise disparate instructions stored in different locations which, when joined logically together, comprise the module and achieve the stated purpose for the module. Further, modules may be stored on a computer-readable medium, which may be, for instance, a hard disk drive, flash device, random access memory (RAM), tape, or any other such medium used to store data.

Indeed, a module of executable code could be a single instruction or many instructions and may even be distributed over several different code segments, among different programs, and across several memory devices. Similarly, operational data may be identified and illustrated herein within modules and may be embodied in any suitable form and organized within any suitable type of data structure. The operational data may be collected as a single data set or may be distributed over different locations, including over different storage devices, and may exist, at least partially, merely as electronic signals on a system or network.

It will be readily understood that the components of the application, as generally described and illustrated in the figures herein, may be arranged and designed in a wide variety of different configurations. Thus, the detailed description of the embodiments is not intended to limit the scope of the application as claimed but is merely representative of selected embodiments of the application.

One having ordinary skill in the art will readily understand that the above may be practiced with steps in a different order and/or with hardware elements in configurations that are different from those which are disclosed. Therefore, although the application has been described based upon these preferred embodiments, it would be apparent to those of skill in the art that certain modifications, variations, and alternative constructions would be apparent. While preferred embodiments of the present application have been described, it is to be understood that the embodiments described are illustrative only, and the scope of the application is to be defined solely by the appended claims when considered with a full range of equivalents and modifications (e.g., protocols, hardware devices, software platforms, etc.) thereto.

What is claimed is:

1. A system comprising:
a storage configured to store one or more statistical models and one or more ray-tracing models; and
a processor configured to
simulate a first portion of an audio impulse response via execution of the one or more ray-tracing models on characteristics of a venue,
predict a second portion of the audio impulse response via execution of the one or more statistical models on the characteristics of the venue,
combine the simulated first portion of the audio impulse response and the predicted second portion of the audio impulse response into a composite audio impulse response, and
display the composite audio impulse response via a user interface.

2. The system of claim 1, wherein the characteristics of the venue comprises geometric attributes of a space, acoustical attributes of the space, location of receiver/listener, and locations of one or more loudspeakers within the space.

3. The system of claim 1, wherein the processor is configured to simulate a head region of the audio impulse response via execution of the one or more ray-tracing models, wherein the head region represents direct sound and early reflections.

4. The system of claim 1, wherein the processor is configured to predict a tail region of the audio impulse response via execution of the one or more statistical methods, wherein the tail region represents reverberation time.

5. The system of claim 4, wherein the processor is configured to predict a rate of decay of the tail region via execution of a first statistical model on the characteristics of the venue, and predict an amplitude of the tail region via execution of a second statistical model on the characteristics of the venue, the simulated first portion, and the predicted rate of decay.

6. The system of claim 1, wherein the processor is configured to calculate one or more of a sound pressure level (SPL), a frequency response (FR), and a speech transmission index (STI) for the composite audio impulse response.

7. The system of claim 1, wherein the processor is configured to simulate the first portion of the audio impulse response and predict the second portion of the audio response signal for a predefined location within the venue.

8. A method comprising:
storing one or more statistical models and one or more ray-tracing models;
simulating a first portion of an audio impulse response via execution of the one or more ray-tracing model on characteristics of a venue;
predicting a second portion of the audio impulse response via execution of the one or more statistical models on the characteristics of the venue;
combining the simulated first portion of the audio impulse response and the predicted second portion of the audio impulse response into a composite audio impulse response; and
displaying the composite audio impulse response via a user interface.

9. The method of claim 8, wherein the characteristics of the venue comprises geometric attributes of a space, acoustical attributes of the space, location of receiver/listener, and locations of one or more loudspeakers within the space.

10. The method of claim 8, wherein the simulating comprise simulating a head region of the audio impulse response via execution of the one or more ray-tracing models, wherein the head region represents direct sound and early reflections.

11. The method of claim 8, wherein the predicting comprises predicting a tail region of the audio impulse response via execution of the one or more statistical methods, wherein the tail region represents reverberation time.

12. The method of claim 11, wherein the predicting comprises predicting a rate of decay of the tail region via execution of a first statistical model on the characteristics of the venue, and predicting an amplitude of the tail region via execution of a second statistical model on the characteristics of the venue, the simulated first portion, and the predicted rate of decay.

13. The method of claim 8, wherein the simulating comprises simulating one or more of a sound pressure level (SPL), a frequency response (FR), and a speech transmission index (STI) for the composite audio impulse response.

14. The method of claim 8, wherein the simulating comprises simulating the first portion of the audio impulse response and predicting the second portion of the audio impulse response for a predefined location within the venue.

15. A computer-readable medium comprising instructions which when executed by a processor cause a computer to perform a method comprising:
storing one or more statistical models and one or more ray-tracing models;
simulating a first portion of an audio impulse response via execution of the one or more ray-tracing model on characteristics of a venue;
predicting a second portion of the audio impulse response via execution of the one or more statistical models on the characteristics of the venue;
combining the simulated first portion of the audio impulse response and the predicted second portion of the audio impulse response into a composite audio impulse response; and
displaying the composite audio impulse response via a user interface.

16. The computer-readable medium of claim 15, wherein the characteristics of the venue comprises geometric attributes of a space, acoustical attributes of a space, location of receiver/listener, and locations of one or more loudspeakers within the space.

17. The computer-readable medium of claim 15, wherein the simulating comprise simulating a head region of the audio impulse response via execution of the one or more ray-tracing models, wherein the head region represents direct sound and early reflections.

18. The computer-readable medium of claim 15, wherein the predicting comprises predicting a tail region of the audio impulse response via execution of the one or more statistical methods, wherein the tail region represents reverberation time.

19. The computer-readable medium of claim 18, wherein the predicting comprises predicting a rate of decay of the tail region via execution of a first statistical model on the characteristics of the venue, and predicting an amplitude of the tail region via execution of a second statistical model on the characteristics of the venue, the simulated first portion, and the predicted rate of decay.

20. The computer-readable medium of claim 15, wherein the simulating comprises simulating one or more of a sound pressure level (SPL), a frequency response (FR), and a speech transmission index (STI) for the composite audio impulse response.
